(19) United States
(12) Patent Application Publication
(10) Pub. No.: US 2026/0327801 A1
(43) Pub. Date: Oct. 22, 2026

(54) ORGANIC PRECURSORS WITH CARBON-CARBON DOUBLE BONDS IN COMBINATION WITH METAL PRECURSORS TO DEPOSIT EUV SENSITIVE FILMS

(71) Applicant: ASM IP Holding B.V., Almere (NL)

(72) Inventors: Kishan Ashokbhai Patel, Leuven (BE); Yoann Francis Tomczak, Leuven (BE); Charles Dezelah, Helsinki (FI)

(21) Appl. No.: 19/645,522

(22) Filed: Apr. 13, 2026

Related U.S. Application Data
(60) Provisional application No. 63/789,662, filed on Apr. 16, 2025.

(51) Int. Cl. C23C 16/455; C23C 16/52; G03F 7/16; H10P 14/60; H10P 76/20

(52) U.S. Cl. CPC C23C 16/45553; C23C 16/45544; C23C 16/52; G03F 7/167; H10P 14/6339; H10P 76/204

(57) ABSTRACT

Methods and related systems for forming an EUV sensitive film on a substrate are provided. A method for forming an extreme ultraviolet (EUV) sensitive film on a substrate comprises at least one cyclical deposition process. The deposition process comprises providing a metal precursor into the reaction chamber in vapor phase and providing an organic precursor selected from an organic precursor comprising a carbon-carbon double bond and/or conjugations, an organic precursor comprising a homobifunctional organic precursor, or an organic precursor comprising a heterobifunctional organic precursor into the reaction chamber in vapor phase. The method may comprise executing a plurality of cyclical deposition cycles.

### CROSS-REFERENCE TO RELATED APPLICATIONS

This application claims priority to U.S. Provisional Patent Application Ser. No. 63/789,662 filed Apr. 16, 2025 titled ORGANIC PRECURSORS WITH CARBON-CARBON DOUBLE BONDS IN COMBINATION WITH METAL PRECURSORS TO DEPOSIT EUV SENSITIVE FILMS, the disclosure of which is hereby incorporated by reference in its entirety.

### FIELD

The present disclosure relates generally to the field of semiconductor processing methods and systems and to the field of device and integrated circuit manufacture. More particularly the present disclosure generally relates to methods for forming extreme ultraviolet (EUV) sensitive films on a substrate and to reactor systems for performing such methods.

### BACKGROUND

During the manufacture of electronic devices, fine patterns of features can be formed on a surface of a substrate by patterning the surface of the substrate and etching material from the substrate surface using, for example, gas-phase etching processes. Photoresists are often used to pattern the surface of a substrate prior to etching. A pattern can be formed in the photoresist by applying a layer of photoresist to a surface of the substrate, masking a surface of the photoresist, exposing an unmasked portion of the photoresist to radiation, such as ultraviolet light, and developing a portion of the photoresist to remove the unmasked or masked portion of the photoresist, while leaving the other of the unmasked and masked portion of the photoresist on the substrate surface.

A photoresist is typically spin-coated onto the surface of the substrate using a liquid solution. While such techniques work relatively well for several applications, spin-on coating techniques may not provide desired (relatively low) thickness or thickness uniformity of the photoresist on the substrate surface. In addition to this, spin-on-resist can require additional adhesion promoter layers to have proper deposition on the wafers. Overall, a spin-on-resist method requires multiple steps to have spin-on-resist deposited on the wafer, which reduces the throughput as well as increase the cost of operation. Another approach is to use organic-inorganic polymers grown by a combination chemical vapor deposition (CVD)/ molecular layer deposition (MLD) method. However, these approaches can result in saturated organic-inorganic polymers, which do not provide strong EUV sensitivity.

Accordingly, improved methods of forming patternable material on the surface of the substrate are desired.

Extreme ultraviolet (EUV) lithography techniques are becoming the mainstream methods for the fabrication of semiconductor devices with the critical dimensions below 20 nm. Limitations of the EUV tools include overcoming the source brightness issues and securing the cost efficiency of the technology. The broad industry consensus to move to EUV lithography has triggered a dramatic increase of interest in resist materials of high sensitivity especially designed for use with the EUV tools in order to meet the strict requirements needed to address these limitations. Improving the EUV sensitivity of resists formed by the spin-on method is not straightforward.

Another limitation with EUV lithography is the penetration depth; with the next generation high numerical aperture EUV tools, the depth of penetration of the beam of radiation will be sub-20-nm. Depositing uniform resist film with sub-20-nm thickness by a conventional spin-coating method may be challenging. Moreover, such thin films do not provide sufficient etch resistance for the pattern transfer by dry/wet etch.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods of forming radiation-sensitive, patternable material on a surface of a substrate and to systems for forming the material. While the ways in which various embodiments of the present disclosure address drawbacks of prior methods are discussed in more detail below, in general, various embodiments of the disclosure provide method of forming relatively thin, uniform radiation-sensitive, patternable material using deposition techniques.

In accordance with examples of the disclosure, a method for forming an extreme ultraviolet (EUV) sensitive film on a substrate by a cyclic deposition process is provided. The method for forming the film can include providing a substrate in a reaction chamber; and executing a cyclical deposition process. The cyclical deposition process may comprise the steps of providing a metal precursor into the reaction chamber in vapor phase; and providing an organic precursor into the reaction chamber in vapor phase, to form an EUV sensitive film on a substrate. In various embodiments the organic precursor is an organic precursor comprising a carbon-carbon double bond and/or conjugations. In various embodiments, the organic precursor is a homobifunctional organic precursor. In various embodiments, the organic precursor is a heterobifunctional organic precursor.

In some embodiments, the deposition process is molecular layer deposition.

In some embodiments, the formed EUV sensitive film has a thickness of 1 nm to 40 nm, a thickness of 1 nm to 20 nm, or a thickness of 1 nm or more and less than 20 nm.

In some embodiments, the organic precursor comprising a carbon-carbon double bond and/or conjugations is selected from the group consisting of fumaric acid, fumaryl chloride, cis-2-butene-1,4-diol, 1,3-butadiene-1,4-diol, the aldehyde of 1,3-butadiene-1,4-diol, the ketone of 1,3-butadiene-1,4-diol, maleic acid, glutaconic acid, muconic acid, citraconic acid, mesaconic acid, itaconic acid, isomers thereof, and acyl halides thereof.

In some embodiments, the organic precursor comprising a carbon-carbon double bond and/or conjugations is fumaric acid.

In some embodiments, the homobifunctional organic precursor comprises a molecule selected from the group consisting of alcohol, amine, thiol, aldehyde, ketone, carboxylic acid, and acyl halide (as known as carboxylic acid halide). In some embodiments, the heterobifunctional organic precursor comprises a molecule selected from the group consisting of alcohol, amine, thiol, aldehyde, ketone, carboxylic acid, and acyl halide.

In some embodiments, the two functional groups in the homobifunctional organic molecule are connected by an alkenyl chain consisting of 1-8 carbon atoms. In some embodiments, the two functional groups in the heterobifunctional organic molecule are connected by an alkenyl chain consisting of 1-8 carbon atoms.

In some embodiments, the two functional groups in the homobifunctional organic molecule or in the heterobifunctional organic molecule are attached to a benzene ring.

In some embodiments, the two functional groups in the homobifunctional organic molecule are attached to separate carbon atoms on a cycloalkane or a cycloalkene comprising from 3 to 8 carbon atoms. In some embodiments, the two functional groups in the heterobifunctional organic molecule are attached to separate carbon atoms on a cycloalkane or a cycloalkene comprising from 3 to 8 carbon atoms.

In some embodiments, the homobifunctional organic precursor is selected from the group consisting of ethylene glycol, benzoquinone, hydroquinone, and benzenedithiol. In some embodiments, the homobifunctional organic precursor is selected from the group consisting of benzoquinone, hydroquinone, and benzenedithiol.

In some embodiments, the metal precursor comprises a metal atom selected from the group consisting of Sn, Ti, Zn, Zr, Sb, Te, Ge, Al, In, Si, and Hf.

In some embodiments, the metal precursor comprises at least one ligand selected from the group consisting of halide, alkyl, neopentyl, amido, alkoxide, alkylamido, and amidinate.

In some embodiments, the process does not comprise providing a coreactant, such as water, ozone, hydrogen, etc., into the reaction chamber in vapor phase.

In some embodiments, the pulse time of the metal precursor is 0.05 to 10 seconds.

In some embodiments, the purge time of the metal precursor is 0.1 to 120 seconds.

In some embodiments, the pulse time of the organic precursor is 0.1 to 30 seconds.

In some embodiments, the purge time of the organic precursor is 1 to 240 seconds.

In some embodiments, the deposition pressure in the cyclical deposition process is 0.1 torr to 50 torr.

In some embodiments, the deposition temperature in the cyclical deposition process is between 50 °C to 250 °C.

In accordance with examples of the disclosure, a reactor system is provided. An exemplary system includes one or more reaction chambers constructed to hold a substrate; a metal precursor vessel constructed and arranged to contain and evaporate a metal precursor; and an organic precursor vessel constructed and arranged to contain and evaporate an organic precursor. Exemplary systems can further include a controller configured to control gas flow of the metal precursor and organic precursor into the one or more reaction chambers to form a film on a substrate comprised in the reaction chamber by means of a method according to one or methods or method steps described herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIG. 2 illustrates a method in accordance with exemplary embodiments of the disclosure.

FIG. 3 illustrates a method in accordance with exemplary embodiments of the disclosure.

FIG. 4 illustrates a method in accordance with exemplary embodiments of the disclosure.

FIG. 5 illustrates a system in accordance with exemplary embodiments of the disclosure.

FIG. 6 illustrates schematically an embodiment of a method of forming an EUV sensitive film in accordance with exemplary embodiments of the disclosure.

FIG. 7 illustrates schematically an embodiment of a method of forming an EUV sensitive film in accordance with exemplary embodiments of the disclosure.

FIG. 8 illustrates an exemplary embodiment of a method of forming a pattern on a substrate.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As used herein, the term “substrate” can refer to any underlying material or materials that can be used to form, or upon which, a device, a circuit, or a film can be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

In some embodiments, “film” refers to a layer extending in a direction perpendicular to a thickness direction. In some embodiments, “layer” refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, “gas” may include material that is a gas at normal temperature and pressure, a vaporized solid and/or a vaporized liquid, and may be constituted by a single gas or a mixture of gases, depending on the context. In some cases, such as in the context of deposition of material, the term precursor can refer to a compound that participates in the chemical reaction that produces another compound, and particularly to a compound that constitutes a film matrix or a main skeleton of a film. In some cases, the terms “precursor” and “reactant” can be used interchangeably. The term “inert gas” refers to a gas that does not take part in a chemical reaction to an appreciable extent and/or an otherwise relatively non-reactive gas from which excited species can be formed (e.g., using a plasma) to excite or interact with a precursor, but unlike a reactant, it may not become a part of a film matrix to an appreciable extent.

The term “cyclic deposition process” or “cyclical deposition process” may refer to the sequential introduction of precursors (and/or reactants) into a reaction chamber to deposit a layer over a substrate and includes processing techniques, such as atomic layer deposition (ALD) and molecular layer deposition (MLD).

The term “atomic layer deposition” (ALD) can refer to a vapor deposition process in which deposition cycles, typically a plurality of consecutive deposition cycles, are conducted in a process chamber.

The term “molecular layer deposition” (MLD) can refer to a vapor deposition process in which deposition cycles, typically a plurality of consecutive deposition cycles, are conducted in a process chamber to form layers comprising organic molecules. MLD is a variant of ALD wherein a precursor is an organic molecule. There are two sub-categories of MLD: fully organic and metalorganic. The present disclosure relates to metalorganic MLD.

The term “metal precursor” can refer to a vapor phase precursor comprising a metal species and/or a semimetal species.

Generally, for ALD/MLD processes, during each deposition cycle, a precursor is introduced to a reaction chamber and is chemisorbed to a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more deposition cycles, e.g., during each step of each cycle, to remove any excess precursor from the process chamber and/or remove any excess reactant and/or reaction byproducts from the reaction chamber.

In this disclosure, continuously can refer to one or more of without breaking a vacuum, without interruption as a timeline, without any material intervening step, without changing one or more conditions, immediately thereafter, as a next step, or without an intervening discrete physical or chemical structure or layer between two structures or layers in some embodiments. For example, a reactant and/or an inert or noble gas can be supplied continuously during two or more steps and/or cycles of a method.

In this disclosure, the term “about” can refer to the exact value or 10% more or less than the value.

The indefinite articles “a” and “an,” as used herein in the specification and in the claims, unless clearly indicated to the contrary, should be understood to mean “at least one.”

The phrase “and/or” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the disclosure, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under,” “underlying,” or “below” will be construed to be relative concepts.

EUV-sensitive layers formed according to methods comprising cyclic deposition processes are provided. The methods for forming the film can include providing a substrate in a reaction chamber; and executing a cyclical deposition process. The cyclical deposition process can comprise the steps of providing a metal precursor into the reaction chamber in vapor phase; and providing an organic precursor selected from (1) an organic precursor comprising a carbon-carbon double bond and/or conjugations, (2) an organic precursor that is a homobifunctional organic precursor, or (3) an organic precursor that is a heterobifunctional organic precursor into the reaction chamber in vapor phase, to form an EUV sensitive film on a substrate. The methods build an organo-metallic framework as the EUV sensitive film.

Uniform and very thin EUV sensitive films (e.g., dry resists that can be applied as a dry film rather than a liquid) can be achieved by employing an ALD/MLD deposition technique, as disclosed herein. Self-limiting layer-by-layer growth particularly helps in controlling the film thickness, as well as uniformity, over the substrate. In addition, EUV sensitive films deposited by ALD/MLD do not require an additional adhesion layer. This is advantageous because it eliminates one step in currently-used approaches. Another advantage of the methods of this disclosure is that different metal-containing compounds/metal centers that have high EUV absorption can be incorporated into the films. Use of high EUV absorption compounds/metal centers can improve the EUV sensitivity of the films.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Described herein are methods of forming EUV-sensitive layers, i.e., layers which are sensitive to extreme ultraviolet light. Extreme ultraviolet light can be described as electromagnetic radiation having a wavelength from at least 1 nm to at most 50 nm. Alternatively, extreme ultraviolet light can be called low-wavelength ultraviolet light or low-energy x-rays.

According to some embodiments of the disclosure, there is described a method for forming an extreme ultraviolet (EUV) sensitive film on a substrate by a cyclic deposition process. The method comprises steps of providing a substrate in a reaction chamber; providing a metal precursor into the reaction chamber in vapor phase; and providing an organic precursor selected from (1) an organic precursor comprising a carbon-carbon double bond and/or conjugations, 2) an organic precursor that is a homobifunctional organic precursor, or (3) an organic precursor that is a heterobifunctional organic precursor into the reaction chamber in vapor phase; to form an EUV sensitive film on a substrate. According to one embodiment, the metal precursor is provided into the reaction chamber before the organic precursor. According to one embodiment, the organic precursor is provided into the reaction chamber before the metal precursor. According to one embodiment, the organic precursor and the metal precursor are provided into the reaction chamber at least partially overlapping.

In some embodiments, a method of forming an EUV-sensitive layer as described herein can be categorized as an atomic layer deposition (ALD) process, or as a molecular layer deposition (MLD) process. Such an EUV-sensitive layer can, after a patterning step, be employed as a mask for a subsequent etch step. Additionally, or alternatively, and after a patterning step, such an EUV-sensitive layer can be employed to locally and selectively grow further material layers on one of exposed and unexposed areas versus the other.

According to one embodiment, the metal precursor comprises a metal atom selected from the group consisting of tin (Sn), titanium (Ti), zinc (Zn), zirconium (Zr), antimony (Sb), tellurium (Te), germanium (Ge), aluminum (Al), indium (In), silicon (Si), and hafnium (Hf).

According to one embodiment, the metal precursor comprises a ligand selected from the group consisting of halide, alkyl, alkyl, neopentyl, amido, alkoxide, alkylamido, and amidinate.

According to one embodiment, the metal precursor comprises at least one ligand selected from the group consisting of halide, alkyl, alkoxide, alkylamido, and amidinate.

According to one embodiment, the organic precursor is an organic precursor comprising a carbon-carbon double bond and/or conjugations.

According to one embodiment, the organic precursor comprising a carbon-carbon double bond and/or conjugations is selected from the group consisting of fumaric acid, fumaryl chloride, cis-2-butene-1,4-diol, 1,3-butadiene-1,4-diol, the aldehyde of 1,3-butadiene-1,4-diol, the ketone of 1,3-butadiene-1,4-diol, maleic acid, glutaconic acid, muconic acid, citraconic acid, mesaconic acid, itaconic acid, isomers thereof, and acyl halides thereof.

According to one embodiment, the organic precursor comprising a carbon-carbon double bond and/or conjugations is fumaric acid.

These organic precursors can have an advantage that a coreactant, such as water, ozone, hydrogen, etc., is not required for the metal precursors. Without being bound by any particular theory or mode of operation, it is believed that the double bonds and conjugations from the organic precursor can be an EUV sensitive component of the film, while different metal centers from metal precursors can be an EUV absorbing component of the film. Upon EUV exposure, the metal center absorbs the radiation thereby providing energy to initiate either cross linking or dissociation of the double bonds. Both mechanisms can provide different kinds of film properties, i.e., negative or positive tone resists, depending on which organic precursor and metal precursor combination is used, and the particular development methods, i.e., wet development or dry development.

According to one embodiment, the organic precursor is an organic precursor comprising a homobifunctional organic precursor. According to one embodiment, the organic precursor is an organic precursor comprising a heterobifunctional organic precursor.

According to one embodiment, the homobifunctional organic precursor comprises a molecule selected from the group consisting of alcohol, amine, thiol, aldehyde, ketone, carboxylic acid, and acyl halide.

According to one embodiment, the two functional groups in the homobifunctional organic molecule are connected by an alkenyl chain consisting of 1-8 carbon atoms.

According to one embodiment, the two functional groups in the homobifunctional organic molecule are attached to a benzene ring.

According to one embodiment, the two functional groups in the homobifunctional organic molecule are attached to separate carbon atoms on a cycloalkane comprising from 3 to 8 carbon atoms. According to one embodiment, the two functional groups in the homobifunctional organic molecule are attached to separate carbon atoms on a cycloalkene comprising from 3 to 8 carbon atoms.

According to one embodiment, the homobifunctional organic precursor is selected from the group consisting of ethylene glycol, benzoquinone, hydroquinone, and benzenedithiol.

According to one embodiment, the homobifunctional organic precursor is selected from the group consisting of benzoquinone, hydroquinone, and benzenedithiol.

These homobifunctional and heterobifunctional organic precursors have an advantage that a coreactant, such as water, ozone, hydrogen, etc., is not required for the metal precursors. Additionally, the probability of having particles inside the films is reduced by eliminating a coreactant. This can simplify the ALD/MLD method to a two-step process, allowing faster precursor switching and increased throughput. The organic precursor provides an EUV sensitive backbone, while different metal centers from metal precursors will be EUV absorbing components of the film. Upon EUV exposure, the metal center absorbs the radiation, then provides energy to initiate dissociation of the organic bonds resulting in a metal/metal oxide film. Both negative and positive tone development can be obtained by selecting a proper development method. Development mechanisms also depend on which organic precursor and metal precursor combination is used with the particular development medium. As an example, metal films rich in an organic component might have higher etch resistant to most acid etchants, while such films may not have a good etch resistance to oxygen and/or hydrogen-based plasma etch compared to its metal/metal oxide counterpart.

According to another aspect of the current disclosure, there is provided a deposition assembly for depositing an EUV sensitive film on a substrate. The assembly comprises one or more reaction chambers constructed and arranged to hold the substrate, a precursor injector system constructed and arranged to provide a metal precursor and an organic precursor selected from an organic precursor comprising a carbon-carbon double bond and/or conjugations, an organic precursor comprising a homobifunctional organic precursor or an organic precursor comprising a heterobifunctional organic precursor into the reaction chamber in a vapor phase. The deposition assembly further comprises a first precursor vessel constructed and arranged to contain and evaporate a metal precursor. The deposition assembly further comprises a second precursor vessel constructed and arranged to contain and evaporate an organic precursor. The deposition assembly is constructed and arranged to provide the metal precursor and the organic precursor via the precursor injector system to the reaction chamber to deposit an EUV sensitive film on the substrate.

In some embodiments, the assembly further comprises a coreactant vessel constructed and arranged to contain and evaporate a coreactant as described in the above disclosure, a coreactant input constructed and arranged to provide the coreactant into the reaction chamber in vapor phase, and the assembly is constructed and arranged to provide the coreactant via the reactant injector system to the reaction chamber. In some embodiments, a coreactant is not needed, therefore the assembly further does not include a coreactant vessel.

In some embodiments, the assembly further comprises a temperature controller for controlling the temperature of the reaction chamber. The temperature in the reaction chamber can be set to be between 50 °C and 250 °C, such as 75 °C and 200 °C, 100 °C and 175 °C or 100°C. and 150 °C.

The disclosure is further explained by the following exemplary embodiments depicted in the drawings. The illustrations presented herein are not meant to be actual views of any particular material, structure, or device, but are merely schematic representations to describe embodiments of the current disclosure. It will be appreciated that elements in the figures are illustrated for simplicity and clarity and have not necessarily been drawn to scale. For example, the dimensions of some of the elements in the figures may be exaggerated relative to other elements to help improve the understanding of illustrated embodiments of the present disclosure. The structures and devices depicted in the drawings may contain additional elements and details, which may be omitted for clarity.

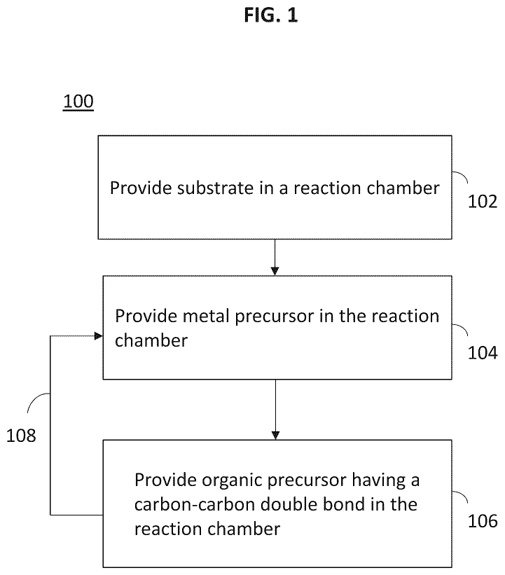

FIGS. 1, 2, 3, and 4 illustrate exemplary embodiments of a method 100, a method 200, a method 300, and a method 400, respectively, according to embodiments of the current disclosure. Each of methods 100, 200, 300, and 400 may be used to form an extreme ultraviolet (EUV) sensitive film on a substrate. The film can be used during formation of a structure or a device, such as a structure and device described herein. However, unless otherwise noted, methods are not limited to such applications.

During step 102 of method 100, step 202 of method 200, step 302 of method 300 or step 402 of method 400, a substrate is provided into a reaction chamber of a reactor. The reaction chamber can form part of an atomic layer deposition (ALD) or molecular layer deposition (MLD) reactor. The reaction chamber may be a single wafer reactor. Alternatively, the reactor may be a batch reactor. Various phases of method 100, method 200, method 300, and method 400 can be performed within a single reaction chamber or they can be performed in multiple reaction chambers, such as reaction chambers of a cluster tool. In some embodiments, the method 100, method 200, method 300, and method 400 can be performed in a single reaction chamber of a cluster tool, but other, preceding or subsequent, manufacturing steps of the structure or device are performed in additional reaction chambers of the same cluster tool. Optionally, a reactor including the reaction chamber can be provided with a heater to activate the reactions by elevating the temperature of one or more of the substrates and/or the reactants and/or precursors.

During step 102, 202, 302 or 402, the substrate can be brought to a desired temperature (i.e., a desired substrate temperature) and pressure for providing a metal precursor into the reaction chamber 104, 204, 304, or 404, and/or for providing an organic precursor into the reaction chamber 106, 206, 306, or 406. A temperature (e.g. of a substrate or a substrate support) within a reaction chamber can be between 50 °C and 250 °C, for example, from about 60 °C to about 200 °C, about 70 °C to about 150 °C, about 70 °C to about 130 °C, or from about 80 °C to about 120 °C. As a further example, a temperature within a reaction chamber can be from about 90 °C to about 110 °C. Exemplary temperatures within the reaction chamber may be 70 °C, 80 °C, 90 °C, 100 °C 110 °C, 120 °C, 130 °C, 150 °C, 170 °C, and 200 °C.

A pressure within the reaction chamber can be less than 50 Torr, for example 40 Torr, 10 Torr, 5 Torr or 2 Torr, 1 Torr, 0.5 Torr, or 0.1 Torr. A pressure within the reaction chamber can be at least 0.1 Torr, such as 0.1 Torr up to and including 50 Torr. Different pressures may be used for different process steps.

A metal precursor is provided into the reaction chamber containing the substrate 104, 204, 304, or 404. Without limiting the current disclosure to any specific theory, the metal precursor may chemisorb on the substrate while providing the metal precursor into the reaction chamber. The duration of providing the metal precursor into the reaction chamber (metal precursor pulse time) may be, for example, 0.01 s, 0.5 s, 1 s, 1.5 s, 2 s, 2.5 s, 3 s, 3.5 s, 4 s, 4.5 s or 5 s. In some embodiments, the duration of providing the metal precursor into the reaction chamber (metal precursor pulse time) may be more than 5 s or more than 10 s or about 20 s.

When an organic precursor comprising a carbon-carbon double bond and/or conjugations is provided into the reaction chamber 106 or 206, it may react with the chemisorbed metal precursor, or its derivate species, to form an EUV sensitive film. When a homobifunctional organic precursor or heterobifunctional organic precursor is provided into the reaction chamber 310 or 410, it may react with the chemisorbed metal precursor, or its derivate species, to form an EUV sensitive film. The duration of providing organic precursor in the reaction chamber (organic precursor pulse time) may be, for example 0.5 s, 1 s, 2 s, 3 s, 3.5 s, 4 s, 5 s, 6 s, 7 s, 8 s, 10 s, 12 s, 15 s, 30 s, 40 s, 50 s or 60 s. In some embodiments, the duration of providing organic precursor in the reaction chamber is less than 15 s or less than 10 s or about 3 s.

In some embodiments, the metal precursor may be heated before providing it into the reaction chamber. In some embodiments, the organic precursor may be heated before providing it into the reaction chamber. In some embodiments, the organic precursor may be kept at ambient temperature before providing it into the reaction chamber.

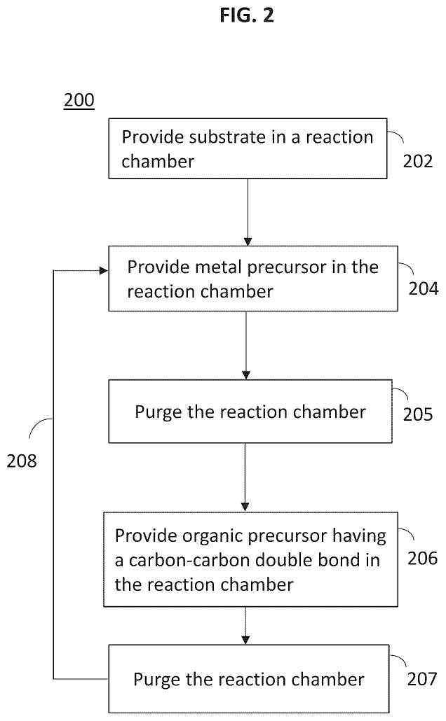

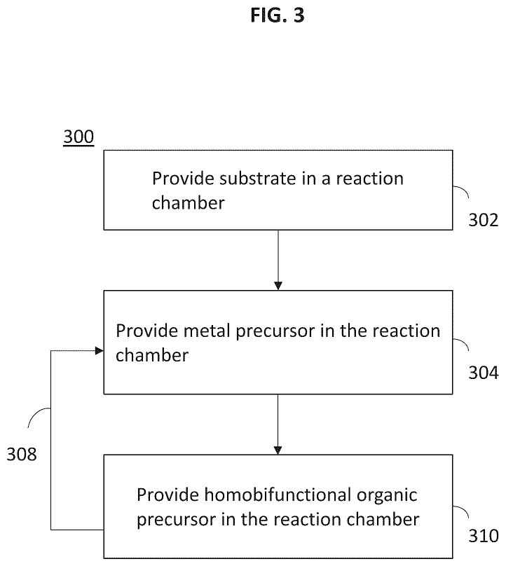

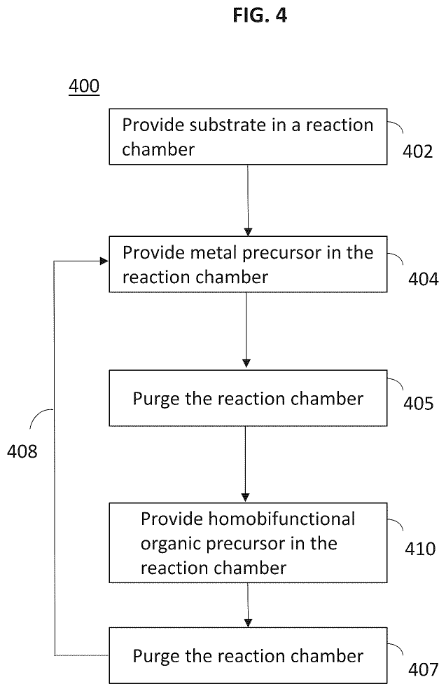

Steps 104 and 106 in FIG. 1, or steps 204 and 206 in FIG. 2, or steps 304 and 310 in FIG. 3, or steps 404 and 410 in FIG. 4, can be performed in any order, and may form a deposition cycle, resulting in the deposition of a material comprising a metal and an organic chain. In some embodiments, the two steps of the deposition, namely providing the metal precursor and the organic precursor comprising a carbon-carbon double bond and/or conjugations in the reaction chamber (104 and 106 or 204 and 206) or the homobifunctional organic precursor or the heterobifunctional organic precursor into the reaction chamber (304 and 310 or 404 and 410), may be repeated (as illustrated loop 108, 208, 308 and 408, respectively). Such embodiments can comprise performing one or more, or several deposition cycles. The thickness of the deposited material may be regulated by adjusting the number of deposition cycles. The deposition cycle (e.g., loop 108) may be repeated until a desired material thickness is achieved. For example, about 5, 10, 15, 20, 25, 30, 40, 50, 100, 150, 200, 250, 300, 400, 500, 600, 700, 800, 1,200 or 1,500 deposition cycles may be performed. In some embodiments, for instance, method 200 (step 204 and step 205) may be repeated in a loop for X number of cycles, and (step 206 and step 207) may be repeated in a loop for Y number of cycles, in (loop 208) for a supercycle deposition. Supercycle depositions can be similarly performed in method 400.

Depending on the deposition conditions, deposition cycle numbers etc., films of variable thickness may be deposited. For example, a film may have an average thickness between approximately 0.2 nm and 60 nm, or between about 0.5 nm and 50 nm, or between about 0.5 nm and 25 nm, or between about 1 nm and 40 nm, or between about 1 nm and 50 nm, or between about 1 nm and 20 nm, or between about 10 nm and 60 nm. A film may have an average thickness of, for example, approximately 0.2 nm, 0.3 nm, 0.5 nm, 1 nm, 1.5 nm, 2 nm, 2.5 nm, 3 nm, 3.5 nm, 4 nm, 4.5 nm, 5 nm, 6 nm, 8 nm, 10 nm, 15 nm, 20 nm, 25 nm, 30 nm, 35 nm, 40 nm, 50 nm, 70 nm, 85 nm or 100 nm. The desired thickness may be selected according to the intended application.

The metal precursor and the organic precursor may be provided into the reaction chamber in separate steps (e.g., step 104 and step 106 in FIG. 1, step 204 and step 206 in FIG. 2, step 304 and step 310 in FIG. 3, and step 404 and step 410 in FIG. 4). For instance, FIG. 2 illustrates an embodiment according to the current disclosure, where steps 204 and 206 are separated by purge steps 205 and 207. In such embodiments, a deposition cycle comprises one or more purge steps 205, 207. FIG. 4 illustrates an embodiment according to the current disclosure, where steps 404 and 410 are separated by purge steps 405 and 407. In such embodiments, a deposition cycle comprises one or more purge steps 405, 407. During purge steps, precursors can be temporally separated from each other by inert gases, such as argon (Ar), nitrogen (N₂) or helium (He) and/or a vacuum pressure. The separation of the metal precursor and the organic precursor may alternatively be spatial. The duration of the purge step 205, after the introduction of the metal precursor 204 (FIG. 2), or the purge step 405, after the introduction of the metal precursor 404 (FIG. 4) may be, for example 0.1 s, 1 s, 2 s, 3 s, 3.5 s, 4s, 5 s, 6 s, 7 s, 8 s, 10 s, 12 s, 15 s, 30 s, 40 s, 50 s or 60 s. The duration of the purge step 207, after the introduction of the organic precursor 206 (FIG. 2) or the purge step 407, after the introduction of the organic precursor 410 (FIG. 4) may be, for example 5 s, 6 s, 7 s, 8 s, 10 s, 12 s, 15 s, 30 s, 40 s, 50 s, 60 s, 80 s, 100 s, or 120 s.

Purging the reaction chamber (e.g., steps 205 and/or 207) in FIG. 2, or purging the reaction chamber (e.g., steps 405 and/or 407) in FIG. 4, may prevent or mitigate gas-phase reactions between a metal precursor and an organic precursor, and enable self-saturating surface reactions. Surplus chemicals and reaction byproducts, if any, may be removed from the substrate surface, such as by purging the reaction chamber or by moving the substrate before the substrate is contacted with the next reactive chemical. In some embodiments, however, the substrate may be moved to separately contact a metal precursor and an organic precursor. Because in some embodiments, the reactions may self-saturate, strict temperature control of the substrates and precise dosage control of the precursors may not be required.

When performing the method 100, method 200, method 300, and method 400, an EUV sensitive film is deposited onto the substrate. The deposition process may be a cyclical deposition process, and may include ALD and MLD.

In some embodiments, the metal precursor is brought into contact with a substrate surface (step[ 204 or step 404), excess metal precursor is partially or substantially completely removed by an inert gas or vacuum (step 205 or step 405) (respectively), and organic precursor is brought into contact with the substrate surface comprising metal precursor (e.g., step 206 (FIG. 2) or step 410 (FIG. 4. The metal precursor may be brought into contact with the substrate surface in one or more pulses (e.g., step 204 or step 404 of FIG. 2 or FIG. 4 respectively). In other words, the pulsing of the metal precursor may be repeated. The metal precursor on the substrate surface may react with the organic precursor to form an EUV sensitive film. Also pulsing of the organic precursor (e.g., step 206 or step 410 of FIG. 2 and FIG. 4 respectively) may be repeated. In some embodiments, the organic precursor may be provided into the reaction chamber prior to the metal precursor (with or without an intervening purge cycle).

For example, if an EUV sensitive film is deposited at a temperature between 50 °C and 250 °C, and the deposition cycle (providing a metal precursor and an organic precursor, separated by purging cycles) is repeated between 5 and 250 times, it may be possible to obtain a material with an average thickness between approximately 1 nm and 40 nm, 2 nm and 40 nm, for example 2 nm, 5 nm, 10 nm, 20 nm, or 30 nm.

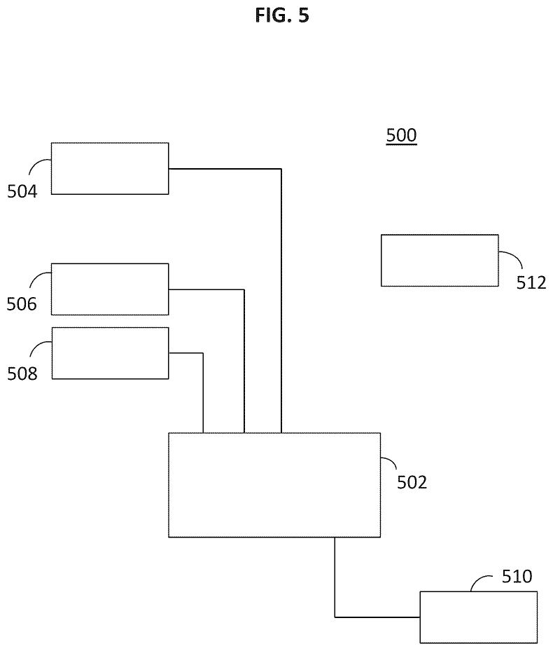

FIG. 5 illustrates a deposition assembly 500 according to the current disclosure in a schematic manner. Deposition assembly 500 can be used to perform a method as described herein and/or to form a structure or a device, or a portion thereof as described herein.

In the illustrated example, deposition assembly 500 includes one or more reaction chambers 502, a precursor injector system 501, a metal precursor vessel 504, organic precursor vessel 506, a purge gas source 508, an exhaust source 510, and a controller 512.

Reaction chamber 502 can include any suitable reaction chamber, such as an ALD, CVD, or MLD reaction chamber.

The metal precursor vessel 504 can include a vessel configured for containing and supplying one or more metal precursors as described herein—alone or mixed with one or more carrier (e.g., inert) gases. Organic precursor vessel 506 can include a vessel configured for containing and supplying and one or more organic precursors as described herein—alone or mixed with one or more carrier gases. Purge gas source 508 can include one or more inert gases as described herein. Although illustrated with three source vessels 504-508, deposition assembly 500 can include any suitable number of source vessels. Source vessels 504-508 can be coupled to reaction chamber 502 via lines 514-518, which can each include flow controllers, valves, heaters, and the like. In some embodiments, the metal precursor in the metal precursor vessel 504 may be heated. In some embodiments, the vessel 504 is heated so that the metal precursor reaches a temperature between about 60 °C and about 200 °C, such as between about 100 °C, and about 145 °C, for example 85 °C, 100 °C, 110 °C 120 °C, 130 °C or 140 °C.

Exhaust source510 can include one or more vacuum pumps, and an abatement system.

Controller 512 includes electronic circuitry and software to selectively operate valves, manifolds, heaters, pumps, and other components included in the deposition assembly 500. Such circuitry and components operate to introduce precursors and purge gases from the respective sources 504-508. Controller 512 can control timing of gas pulse sequences, temperature of the substrate and/or reaction chamber 502, pressure within the reaction chamber 502, and various other operations to provide proper operation of the deposition assembly 500. Controller 512 can include control software to control valves electrically or pneumatically to control flow of precursors and purge gases into and out of the reaction chamber 502. Controller 512 can include modules such as a software or hardware component, which perform certain tasks. A module may be configured to reside on the addressable storage medium of the control system and be configured to execute one or more processes.

Other configurations of deposition assembly 500 are possible, including different numbers and kinds of precursor and reactant sources and purge gas sources. Further, it will be appreciated that there are many arrangements of valves, conduits, precursor sources, and purge gas sources that may be used to accomplish the goal of selectively and in a coordinated manner feeding gases into reaction chamber 502. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 500, substrates, such as semiconductor wafers (not illustrated), are transferred from, e.g., a substrate handling system to reaction chamber 502. Once substrate(s) are transferred to reaction chamber 502, one or more gases from gas sources 504-508, such as precursors, reactants, carrier gases, and/or purge gases, are introduced into reaction chamber 502.

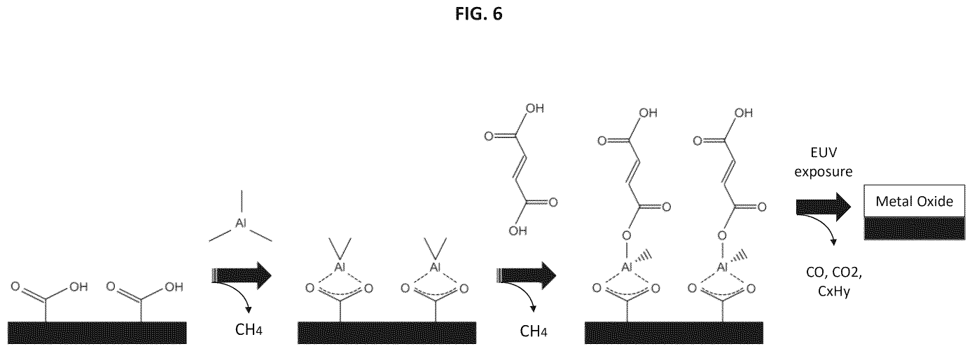

In an example, reference is made to FIG. 6, which schematically shows an embodiment of a method of forming an EUV sensitive film as described herein. In the embodiment shown, one or more deposition cycles are carried out. A deposition cycle can comprise a first pulse and a second pulse. The first pulse comprises exposing the substrate to trimethylaluminum (TMA). The second pulse comprises exposing the substrate to fumaric acid. An EUV sensitive film is formed. Selecting the number of deposition cycles allows for control of the average thickness of the EUV-sensitive layer, with a higher number of deposition cycles corresponding to thicker EUV-sensitive layers. Thus, an EUV sensitive film comprising an inorganic-organic hybrid polymer film is formed on the substrate. The substrate can then be exposed to EUV radiation through a photomask to form exposed and unexposed areas on the substrate. In the unexposed areas, the EUV sensitive film remains substantially unaffected. In the exposed areas, the EUV sensitive film is at least partially decomposed under the influence of the EUV radiation, to form volatile reaction products such as CO, CO₂, CₓH_{y}, and optionally further forming organic residue or scum. In the current example, the decomposed film is a film having a composition comprising an atomic percentage of Al, O, C, and H. In some embodiments, the atomic percentage of carbon (C) in the exposed area is lower than the atomic percentage of carbon (C) of the unexposed area. The composition of the decomposed film and other films formed by the methods discloses herein may be determined by a number of techniques, including, but limited to, X-ray fluorescence (XRF), inductively coupled plasma mass spectrometry (ICP-MS), and energy-dispersive X-ray spectroscopy (EDS).

It shall be understood that “EUV radiation” can refer to electromagnetic radiation having a wavelength of at least 10 nm to at most 100 nm, or of at least 11 nm of at most 50 nm, or of at least 12 nm to at most 20 nm, or of at least 13 nm to at most 14 nm.

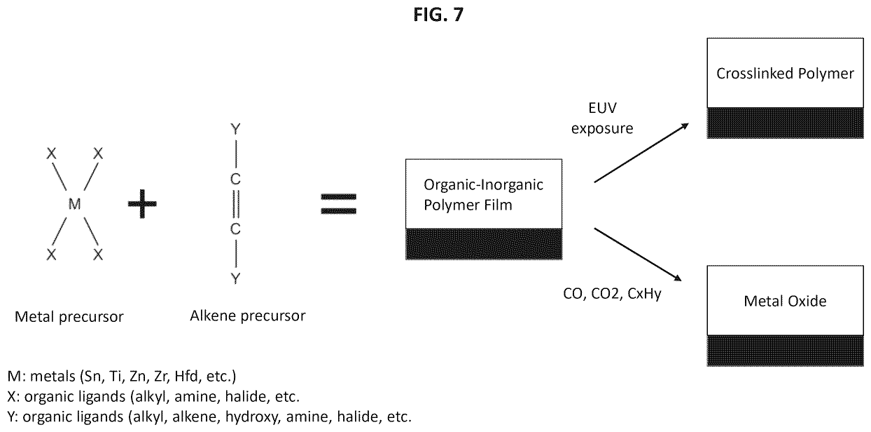

In another example, reference is made to FIG. 7, which schematically shows an embodiment of a method for forming an EUV sensitive film as described herein. In the embodiment shown, one or more deposition cycles are carried out. A deposition cycle can comprise a first pulse and a second pulse. The first pulse comprises exposing the substrate to a metal precursor. The second pulse comprises exposing the substrate to an organic precursor, for example an organic precursor comprising a carbon-carbon double bond and/or conjugation (FIG. 7). An EUV sensitive film is formed. Selecting the number of deposition cycles allows for control of the average thickness of the EUV-sensitive layer, with a higher number of deposition cycles corresponding to thicker EUV-sensitive layers. Thus, an EUV sensitive film comprising an organic polymer film is formed on the substrate. The substrate can then be exposed to EUV radiation through a photomask to form exposed and unexposed areas on the substrate. In the unexposed areas, the EUV sensitive film remains substantially unaffected. In the exposed areas, the EUV sensitive film is at least partially decomposed under the influence of the EUV radiation to form volatile reaction products such as CO, CO₂, CₓH_{y} (FIG. 7), and optionally further forming organic residue or scum. FIG. 7 depicts two possible pathways for the photosensitive film to change under EUV exposure. The pathway on the upper right is when the carbon-carbon double bond crosslinks and forms a polymeric network on the substrate. The pathway on the lower right is when the organic molecule breaks/decomposes during EUV exposure resulting in metal oxide films. It is to be noted that the remaining film on the substrate after EUV exposure can be something other than a pure metal oxide, e.g., it can be metal oxycarbide, metal carbide, metal oxide with carbon impurity or carbon inclusions, etc.

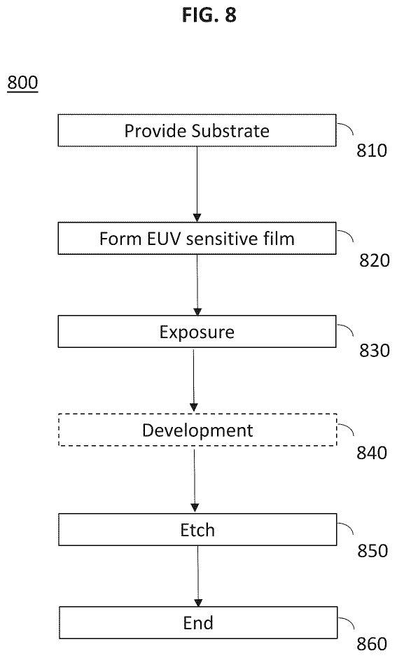

In a further example, reference is made to FIG. 8. FIG. 8 shows an exemplary embodiment of a method 800 for forming a pattern on a substrate. The method 800 comprises a step of providing a substrate 810. Then, an EUV sensitive film is formed on the substrate (step 820) by way of a method as described herein. The EUV sensitive film is then exposed to EUV radiation (step 830), thus forming exposed areas and unexposed areas. After EUV exposure(step 830), the EUV sensitive film can optionally be developed (step 840) using resist development techniques which, as such, are known in the Art. Exemplary developers include aqueous solutions of tetramethylammonium hydroxide, aqueous solutions of potassium hydroxide, aqueous solution of hydrochloric acid, aqueous solution of ammonium hydroxide, aqueous solution of phosphoric acid, and methyl isobutyl ketone (MIKP) mixed with isopropyl alcohol (IPA). In such embodiments, substrate exposure to a developer solution can be useful, for example to remove resist residues from exposed areas. The present exemplary embodiment further comprises an etching step 850 in which the substrate is exposed to an etchant. The etchant can advantageously etch a surface layer of the substrate selectively vis-à-vis unexposed areas or exposed areas of the EUV sensitive film. It shall be understood that suitable etching chemistries are, as such, described in the Art, and include fluorine-based etching chemistries employing a plasma gas comprising a fluorine-containing etchant such as SF₆, C₄F₈ or CF₄, and oxygen-based etching chemistries. After the etching step 850, a method according to the presently described embodiment ends 860. Thus, the surface layer of a substrate can be patterned. The substrate can then be subjected to further processing steps, as needed.

The illustrations presented herein are not meant to be actual views of any particular material, structure, or device, but are merely idealized representations that are used to describe embodiments of the disclosure.

The particular implementations shown and described are illustrative of the invention and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationships or physical connections may be present in the practical system, and/or may be absent in some embodiments.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

What is claimed is:

1. A method for forming an extreme ultraviolet (EUV) sensitive film on a substrate by a cyclic deposition process, the method comprising:
providing a substrate into a reaction chamber; and executing a cyclical deposition process, the cyclical deposition process comprising the following steps i-ii:
i. providing a metal precursor into the reaction chamber in the vapor phase; and
ii. providing an organic precursor selected from an organic precursor comprising a carbon-carbon double bond and/or conjugations, an organic precursor comprising a homobifunctional organic precursor, or an organic precursor comprising a heterobifunctional organic precursor into the reaction chamber in the vapor phase to form an EUV sensitive film on the substrate.

2. The method according to claim 1, wherein the cyclic deposition process is a molecular layer deposition.

3. The method according to claim 1, wherein the EUV sensitive film has an average thickness between 1 nm and 40 nm.

4. The method according to claim 1, wherein the organic precursor comprising a carbon-carbon double bond and/or conjugations is selected from the group consisting of fumaric acid, fumaryl chloride, cis-2-butene-1,4-diol, 1,3-butadiene-1,4-diol, the aldehyde of 1,3-butadiene-1,4-diol, the ketone of 1,3-butadiene-1,4-diol, maleic acid, glutaconic acid, muconic acid, citraconic acid, mesaconic acid, itaconic acid, isomers thereof, and acyl halides thereof.

5. The method according to claim 1, wherein the organic precursor comprising a carbon-carbon double bond and/or conjugations is fumaric acid.

6. The method according to claim 1, wherein the homobifunctional organic precursor or the heterobifunctional organic precursor comprises a molecule selected from the group consisting of alcohol, amine, thiol, aldehyde, ketone, carboxylic acid, and acyl halide.

7. The method according to claim 6, wherein the two functional groups in the homobifunctional organic molecule or the heterobifunctional organic precursor are connected by an alkenyl chain consisting of 1-8 carbon atoms.

8. The method according to claim 6, wherein the two functional groups in the homobifunctional organic molecule or in the heterobifunctional organic molecule are attached to a benzene ring.

9. The method according to claim 6, wherein the two functional groups in the homobifunctional organic molecule or in the heterobifunctional organic molecule are attached to separate carbon atoms on a cycloalkane or a cycloalkene comprising from 3 to 8 carbon atoms.

10. The method according to claim 1, wherein the homobifunctional organic precursor is selected from the group consisting of ethylene glycol, benzoquinone, hydroquinone, and benzenedithiol.

11. The method according to claim 1, wherein the metal precursor comprises a metal atom selected from the group consisting of Sn, Ti, Zn, Zr, Sb, Te, Ge, Al, In, Si, and Hf.

12. The method according to claim 11, wherein the metal precursor comprises at least one ligand selected from the group consisting of halide, alkyl, alkyl, neopentyl, amido, alkoxide, alkylamido, and amidinate.

13. The method according to claim 1, wherein the cyclic deposition process does not comprise providing a coreactant into the reaction chamber in vapor phase.

14. The method according to claim 1, wherein a pulse time of the metal precursor is 0.05 to 10 seconds.

15. The method according to claim 1, wherein a purge time of the metal precursor is 0.1 to 120 seconds.

16. The method according to claim 1, wherein a pulse time of the organic precursor is 0.1 to 30 seconds.

17. The method according to claim 1, wherein a purge time of the organic precursor is 1 to 240 sec.

18. The method according to claim 1, wherein deposition pressure in the cyclical deposition process is 0.1 torr to 50 torr.

19. The method according to claim 1, wherein deposition temperature in the cyclical deposition process is between 50 °C to 250 °C

20. A system comprising: one or more reaction chambers constructed to hold a substrate; a metal precursor vessel constructed and arranged to contain and evaporate a metal precursor; a vessel constructed and arranged to contain and evaporate an organic precursor; and a controller, wherein the controller is configured to control gas flow of the metal precursor and the organic precursor into the one or more reaction chambers to form a film on a substrate comprised in the reaction chamber by the method according to claim 1.
